(19) United States
(12) Patent Application Publication
(10) Pub. No.: US 2025/0072289 A1
(43) Pub. Date: Feb. 27, 2025

(54) BULK-MATERIAL BASED FLEXIBLE THERMOELECTRIC GENERATORS FOR HEAT CONCENTRATION AND DISSIPATION

(71) Applicants: MASSACHUSETTS INSTITUTE OF TECHNOLOGY, Cambridge, MA (US); SOUTHERN UNIVERSITY OF SCIENCE AND TECHNOLOGY, Shenzhen (CN)

(72) Inventors: Qian XU, Cambridge, MA (US); Gang CHEN, Cambridge, MA (US); Weishu LIU, Shenzhen (CN); Biao DENG, Shenzhen (CN); Pengxiang ZHANG, Shenzhen (CN)

(21) Appl. No.: 18/704,812

(22) PCT Filed: Jan. 28, 2023
(86) PCT No.: PCT/CN2023/073513

§ 371 Date: Apr. 25, 2024

Related U.S. Application Data
(60) Provisional application No. 63/302,066, filed on Jan. 22, 2022.

(51) Int. Cl. H10N 10/17

(52) U.S. Cl. CPC H10N 10/17

(57) ABSTRACT

The present disclosure generally relates to high-performance flexible thermoelectric generators (f-TEGs) for heat concentration and dissipation. In some embodiments, the f-TEGs can be incorporated into wearable devices. The f-TEG device can include an f-TEG network of thermoelectric units that include multifunctional thin copper disks that can be used as electrodes, heat concentrators and spreaders, spacers, and flexibility enablers. Each electrode can include a spacer extending therefrom to suppress the heat loss between the hot and the cold sides through conduction and convection across a thermoelectric pillar disposed therebetween. In some embodiments, the f-TEG network can be associated with a fabric to provide good wearability and comfort even in wet thermal environments.

### CROSS REFERENCE TO RELATED APPLICATION

The present disclosure claims priority to and the benefit of U.S. Provisional Application No. 63/302,066, entitled “A Bulk Material-Based Flexible Thermoelectric Generator featuring Multifunctional Copper Electrodes for Heat Concentration and Dissipation and Fabrics for Comfort and Heat-Leakage Reduction,” filed on Jan. 22, 2022, the content of which is incorporated by reference herein in its entirety.

### FIELD

The present disclosure relates to flexible thermoelectric generators (t-TEGs) for heat concentration and dissipation, and more specifically relates to wearable f-TEG devices having multifunctional copper electrodes with optimized designs intended to absorb heat from the wearer and dissipate the heat to the ambient environment for maximum power output and efficiency.

### BACKGROUND

Wearable technologies have seen increasing deployment and are fueling the spread of the Internet of Things (IoT) revolution. For example, thermoelectric generators (TEGs) that convert temperature differences into electrical energy can provide power to wearable devices and other IoT devices. Conventional thermoelectric generators sandwich thermoelectric pillars between ceramic substrates and are thus incapable of bending, which renders them unsuitable for wearable devices. Several strategies have been developed to address the inflexibility of conventional TEGs in recent years, including but not limited to, the use of low-dimensional flexible thermoelectric materials, organic or hybrid (organic plus inorganic) thermoelectric materials, distribution of discrete conventional rigid thermoelectric pillars on a flexible substrate or in a flexible matrix material, painting/printing/deposition of thermoelectric materials onto a flexible substrate or into flexible matrix materials, and/or architectural solutions using very thin electronic materials to form flexible thermoelectric generators (f-TEGs). The resulting f-TEGs, however, have not been translated into practical applications, due, at least in part, to the high fabrication costs because many require relatively complex fabrication steps, including curing polymers and patterning parts with optical lithography, and low output power density (from nW/cm² to a few μW/cm²).

Most research to enhance a thermoelectric system's performance focuses on improving materials' figure of merit (zT) to get a higher energy conversion efficiency. The improvement in the overall performance of a wearable thermoelectric system by enhancing thermoelectric materials' properties is relatively limited at least because the thermal resistance in the substrate materials and interfaces (between body and the device and between the device and ambient air) tends to be more significant than that of thermoelectric pillars, leading to a small temperature drop across the thermoelectric materials and thus low power output. Though the temperature difference between the skin and the ambient air can be up to an approximate range of about 10° C. to about 20° C., the temperature difference across the thermoelectric materials that generates power is usually 1° C. or less, thereby limiting the performance off-TEGs, even if those f-TEGs are made of state-of-the-art thermoelectric materials. Moreover, f-TEGs based on thin-film, fiber, or low-dimensional thermoelectric materials have an even bigger challenge because of the much smaller thickness d, not to mention that the figure-of-merit of these materials has not yet been conclusively demonstrated to be able to compete against bulk materials.

Accordingly, there is a need for low-cost and high-performance f-TEGs with increased power output that can be scalably fabricated and readily incorporated into wearable devices.

### SUMMARY

The present application is directed to bulk-material based flexible thermoelectric generators (f-TEGs) that comprise a wearable f-TEG device that includes an f-TEG network made up of a plurality of thermoelectric units. Each thermoelectric unit of the f-TEG network 100 can include multifunctional copper electrodes and a thermoelectric pillar separated by spacers from each of the electrodes. The electrodes of the f-TEG device of the present embodiments can remove ceramics, polymers, and/or other insulative materials that are common in conventional thermoelectric generators and allows the top and bottom electrodes to be exposed to the ambient air and contact a skin surface directly, respectively. This configuration of the thermoelectric units can make the f-TEG network flexible and removes the redundant thermal resistance of the conventional f-TEG device, which significantly improves power generation performance thereof.

One exemplary flexible thermoelectric generator device includes a thermoelectric generator network that comprises a first thermoelectric unit that includes each of a top electrode, a bottom electrode, and a pillar. The top electrode includes a first spacer extending a first length from the top electrode, the top electrode being defined by an area A₃. The bottom electrode includes a second spacer extending a second length from the bottom electrode, towards the first spacer, with the bottom electrode being defined by an area A₁ and being a distance h₁ apart from the top electrode. The pillar is disposed between the first spacer and the second spacer to separate the first spacer from the second spacer, with the pillar being configured to transmit thermal energy between the top and bottom electrodes. The pillar is defined by an area A₂ and a height h₂ that is independent of the distance h₁. The area A₃ is larger than the area A₁, and a ratio of the areas A₂/A₁ is based on the height h₂ of the pillar or the height h₂ of the pillar is based on the ratio of the areas A₂/A₁.

The device can further include a second thermoelectric unit that can include a top electrode having a third spacer extending from the top electrode, a bottom electrode having a fourth spacer extending from the bottom electrode, towards the third spacer, and a pillar disposed between the top and bottom electrodes. The top electrode of the second thermoelectric unit can be connected to the top electrode of the first thermoelectric unit via a wire, and/or the bottom electrode of the second thermoelectric unit can be connected to the bottom electrode of the first thermoelectric unit via a wire. In some embodiments, the device can be a wearable device. The flexibility of the wearable device can be such that the wearable device is configured to be bent upon itself. For example, it can be bend upon itself at a bending radius in approximately a range of about 1 centimeter to about 10 centimeters. The device can further include a fabric disposed between the top and bottom electrodes. The fabric can include a plurality of openings and/or it can be loosely knitted. In either or both instances, the pillar can pass through the fabric.

A temperature difference defined across the distance h₁ can be lower than a temperature difference defined across the distance h₁ in the absence of the first spacer or the second spacer. In some embodiments, the top and bottom electrodes can be substantially devoid of an insulative material. The bottom electrode can be configured to abut a skin surface to absorb heat from the skin and the top electrode can be configured to dissipate heat from the device and into an ambient environment. The thermoelectric generator network can produce a maximal power density approximately in the range of about 5 μW/cm² to about 60 μW/cm².

A height h₂ of the pillar can be smaller than the distance h₁. The height h₂ of the pillar can be substantially equal to one or more of the first length and the second length. In some embodiments, the distance h₁ can be substantially equal to a sum of h₂ of the pillar, the first length, and the second length. The height h₂ of the pillar can be substantially equal to each of the first length or the second length. One or more of the first length or the second length can be determined based on the distance h₁ or the height h₂.

An optimal area ratio of the areas A₂/A₁ can be based on one or more of the distance h₁, the height of thermoelectric pillar h₂, thermal properties of the materials used in the thermoelectric generator network, thermal contact resistance between the thermoelectric material and the electrodes, or a heat transfer coefficients at the surfaces of the top and bottom electrodes. In some embodiments, an optimal area ratio of the areas A₂/A₁ can be based on the distance h₁, the height of thermoelectric pillar h₂, thermal properties of the materials used in the thermoelectric generator network, thermal contact resistance between the thermoelectric material and the electrodes, and heat transfer coefficients at the surfaces of the top and bottom electrodes. A ratio of the area A₃ to the area A₁ can be approximately in a range of about 1 to about 25.

One exemplary embodiment of a flexible thermal generator network includes a plurality of thermoelectric units, with each thermoelectric unit including a top electrode, a bottom electrode, and a pillar. The top electrode is defined by an area A₃. The bottom electrode is defined by an area A₁ disposed a distance h₁ apart from the top electrode. The pillar is defined by an area A₂ and a height h₂, with the pillar being disposed between the first electrode and the second electrode to be engaged between a first portion of the first electrode and a second portion of the second electrode. At least a pair of the top electrodes of the plurality of thermoelectric units are connected to one another and at least a pair of the bottom electrodes of the plurality of thermoelectric units are connected to one another. The height h₂ of the pillar is smaller than a distance h₁ between the top and bottom electrodes, and the area A₃ is greater than or equal to the area A₁, which is greater than area A₂.

The first portion can further include a first spacer extending from the top electrode and the second portion can further include a second spacer extending from the bottom electrode, with the first and second spacers being configured to engage the pillar therebetween. The top and bottom electrodes and the first and second spacers can be comprised of the same material. In some embodiments, the plurality of thermoelectric units can be substantially devoid of one or more of ceramics, polymers, substrates, or insulative materials between the top and bottom electrodes. Each of the top and bottom electrodes can be substantially devoid of contact with a substrate. One or more of the top electrode or the bottom electrode can include a chamfered edge configured to prevent the edges of thermoelectric units from cutting skin.

An output power density of the thermoelectric unit having the first and second spacers can be about 3 times to about 5 times greater than the output power density of a thermoelectric unit that is devoid of the first and second spacers, with the output power density of the thermoelectric unit that is devoid of the first and second spacers being measured at a same cross-sectional area and thermal condition as the thermoelectric unit. An output power density can increase with the convective heat transfer coefficient above the pair of top electrodes and can be a non-linear function of the height h₂. In some embodiments, the distance h₁ can be substantially equal to a sum of h₂ of the pillar, the first length, and the second length.

### BRIEF DESCRIPTION OF THE DRAWINGS

This disclosure will be more fully understood from the following description taken in conjunction with the accompanying drawings, in which:

FIG. 1 is a schematic perspective view of one embodiment of an f-TEG network made up of a plurality of thermoelectric (TE) units;

FIG. 2A is a schematic perspective cross-sectional view of a thermoelectric unit of the f-TEG network of FIG. 1;

FIG. 2B is a schematic illustration of a thermal resistance circuit based on the structure of the thermoelectric unit of FIG. 2A;

FIG. 2C is a graph illustrating a calculated maximum output power density (maximum output power divided by the total area of top electrodes NA₃ where N is the number of units) as a function of thermoelectric pillar height;

FIG. 2D is a graph illustrating an optimal area ratio (the cross-section area of the thermoelectric pillar to the area of the bottom electrode) as a function of thermoelectric pillar height;

FIG. 3 is a graph illustrating a calculated maximum output power and temperature difference across the thermoelectric pillar as a function of the thermoelectric pillar height;

FIG. 4 is a top view of one embodiment of a fabric that can be associated with the f-TEG network of FIG. 1 to form an f-TEG device;

FIG. 5A is a schematic top view of a first step of a fabrication process of an f-TEG device;

FIG. 5B is a schematic top view of a second step of the fabrication process of the f-TEG device provided for in FIG. 5A;

FIG. 5C is a schematic top view of a third step of the fabrication process of the f-TEG device provided for in FIG. 5A;

FIG. 5D is a schematic top view of a fourth step of the fabrication process of the f-TEG device provided for in FIG. 5A;

FIG. 6A is a perspective view of the f-TEG device manufactured by the fabrication process of FIGS. 5A-5D;

FIG. 6B is a perspective view of a distribution density of the f-TEG device of FIG. 6A;

FIG. 6C is a perspective view illustrating the flexibility of the f-TEG device of FIG. 6A;

FIG. 7 is a perspective view of one embodiment of a standalone f-TEG device devoid of a fabric;

FIG. 8A is a perspective view of a setup for indoor testing of the f-TEG device of FIG. 6A with tunable wind speed and air temperature;

FIG. 8B is a graph illustrating power generation curves of an f-TEG device with 50 pairs of p/n thermoelectric units as a function of sweeping current when a wearer wears it on the forehead under various indoor thermal conditions at a wind speed of about 0.2 m/s;

FIG. 8C is a graph illustrating power generation curves of an f-TEG device with 50 pairs of p/n thermoelectric units as a function of sweeping current when a wearer wears it on the forehead under various indoor thermal conditions at a wind speed of about 2 m/s;

FIG. 8D is a perspective view of a setup for outdoor testing of the f-TEG headband with 50 pairs of thermoelectric units connected to a 1Ω external resistance and the output voltage is recorded by a portable data logger;

FIG. 9A is a schematic side view of a conventional f-TEG unit, which does not include a spacer(s), illustrating a temperature distribution across the same; and

FIG. 9B is a schematic side view of the f-TEG unit of FIG. 2A, which includes a spacer, illustrating a temperature distribution across the same.

### DESCRIPTION

Certain exemplary embodiments will now be described to provide an overall understanding of the principles of the structure, function, manufacture, and use of the systems, devices, and methods disclosed herein. One or more examples of these embodiments are illustrated in the accompanying drawings. Those skilled in the art will understand that the systems, compositions, and methods specifically described herein and illustrated in the accompanying drawings are non-limiting exemplary embodiments and that the scope of the present disclosure is defined solely by the claims. The features illustrated or described in connection with one exemplary embodiment may be combined with the features of other embodiments. Such modifications and variations are intended to be included within the scope of the present disclosure. Further, to the extent features, steps, actions, and the like are described as being “first,” “second,” “third,” etc., such numerical ordering is generally arbitrary, and thus such numbering can be interchangeable unless otherwise known to those skilled in the art.

Like-numbered components across embodiments generally have similar features unless otherwise stated or a person skilled in the art would appreciate differences based on the present disclosure and/or his/her knowledge. Accordingly, aspects and features of every embodiment may not be described with respect to each embodiment, but those aspects and features are applicable to the various embodiments unless statements or understandings are to the contrary. The present disclosure includes some illustrations and descriptions that include prototypes or bench models. A person skilled in the art will recognize how to rely upon the present disclosure to integrate the techniques, systems, devices, and methods provided for into a product, such as a bulk-material, fabric, and/or textile, among other uses

At least one novel aspect of the present disclosure generally relates to a flexible thermoelectric generator (f-TEG) network being included in a wearable device to achieve a higher-performance body-powered f-TEG device. F-TEGs can be promising solutions to provide a power supply for wearable devices, however, the high fabrication costs and low output power density of conventional f-TEGs have limited their applications in this capacity. The present disclosure provides a bulk-material-based f-TEG featuring multifunctional copper electrodes for heat concentration and dissipation and fabrics for comfort and heat-leakage reduction that are scalable and have a low cost of manufacture. The low-cost and high-performance f-TEG of the present embodiments can therefore offer an even wider prospect for low-power electronics used in conjunction with the Internet of Things.

The f-TEG network of the present embodiments can include a plurality of thermoelectric (TE) units arranged in various patterns and connected via copper wires. The TE units can include multifunctional thin copper disks that can be used as electrodes, heat concentrators and spreaders, spacers, and/or flexibility enablers. Copper spacers and fabrics can be used to suppress the heat loss between the hot and the cold sides through conduction and convection and provide good wearability and comfort even in humid environments and/or when exposed to perspiration. The f-TEG network of the present embodiments can increase flexibility and power output as compared to conventional thermoelectric generators, while the design of the network can increase heat concentration and dissipation from the wearer. Given that most conventional wearable electronics can use a microwatt to milliwatt level of power input, developing f-TEGs with higher output power density may be important for bringing self-powered devices from concept to reality. Rather than focusing on the nature of the thermoelectric materials that are used, as is popular in conventional research, innovative device designs for f-TEG devices, such as those discussed in the present disclosure, can have a far greater impact on the power output of thermoelectric devices.

f-TEG Structure and Design Principles

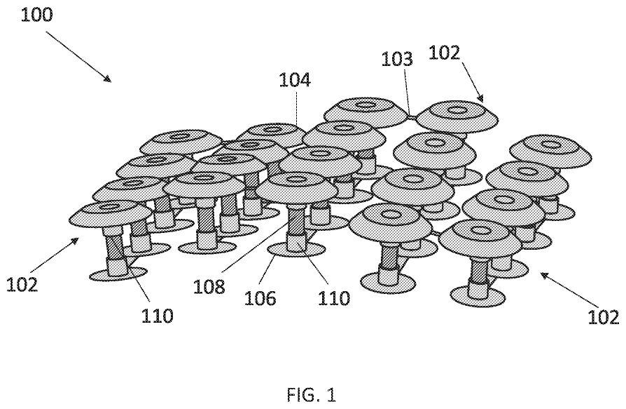

FIG. 1 illustrates an f-TEG network 100 of the present embodiments. The f-TEG network 100 can be incorporated into a wearable f-TEG device 10 for heat concentration and dissipation from a skin surface of the wearer. As shown, the f-TEG network 100 can include one or more thermoelectric units 102. The thermoelectric units 102 can be arranged in a series of rows and/or columns, or any of a variety of patterns, e.g., a circular distribution, to form the f-TEG network 100 that can maximize output power density while maintaining flexibility that can contour to a skin surface of the wearer. Each TE unit 102 can be connected to one or more of the other TE units in the f-TEG network 100 by wires 103, e.g., copper wires, though other compounds can be used in addition to, or in lieu of, copper, to provide a current path between each unit. For example, in some embodiments, each TE unit 102 can be connected to one or more of the other TE units in series to add the generated voltage to one another. A diameter of the wires 103 can be less than about 2 millimeters, e.g., approximately in a range of about 0.1 millimeters to about 2 millimeters, or about 0.2 millimeters to about 1 millimeters, or about 0.3 millimeters to about 0.8 millimeters, or be about 0.4 millimeters. In some embodiments, the wires 103 can be formed into thin strips having a width, or thickness, of less than about 2 millimeters, e.g., approximately in a range of about 0.1 millimeters to about 2 millimeters, or about 0.2 millimeters to about 1 millimeters, or about 0.3 millimeters to about 0.8 millimeters, or be about 0.4 millimeters. Whether in a more circular or cylindrical shape, or in a flatter strip shape, the shape and sizes of the wires can promote flexibility and cost savings while not negatively impacting the heat transfer model.

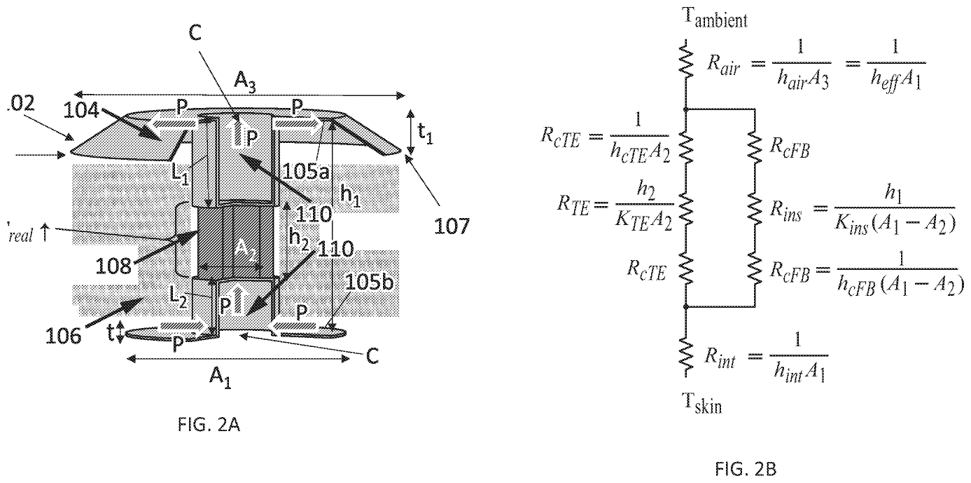

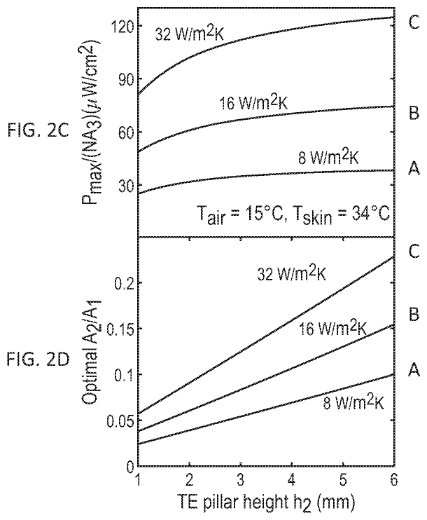

FIG. 2A illustrates in greater detail the thermoelectric (TE) units 102 that make up the f-TEG network 100 of FIG. 1. In addition to optimization of the output power density by the arrangement of the f-TEG network 100, each TE unit 102 of the f-TEG network 100 can be designed to optimize power output while maintaining flexibility for the purpose of being comfortably worn. For example, the TE units 102 can be mushroom-shaped, as shown, though it will be appreciated that this shape is merely exemplary and alternate designs can be used to reduce the parasitic resistances, maximize the temperature difference across a length of the TE unit 102, and/or achieve flexibility. Still further, in addition to one or more individual TE units 102 being designed to maximize power output while maintaining flexibility, the configuration of multiple such units to form a network can be such that power output is maximized while flexibility is maintained across the network, e.g., the f-TEG network 100.

The TE unit 102 can include a top electrode 104 and a bottom electrode 106 that define a height h₁ or thickness of the TE unit 102, therebetween, with the height h₁ being measured between the flat inner surfaces 105a, 105b of each electrode. As shown, the top and bottom electrodes 104, 106 can include multifunctional disks to facilitate heat concentration via absorption and/or heat dissipation therefrom. For example, each of the top electrode 104 and the bottom electrode 106 can be referred to as having a “hot side” and a “cold side,” with the “hot side” being adjacent to a wearer and the “cold side” being free of adjacent structures to allow for dissipation of thermal energy into the ambient air. A person skilled in the art will recognize that a temperature of the hot side can be an average skin temperature of a human, e.g., approximately in a range of about 32° C. to about 37° C., or about 34° C., while a temperature of the cold side can be an average ambient air temperature, e.g., approximately in a range of about 10° C. to about 25° C., or about 15° C. It will be appreciated that a shape of the electrodes of the presently disclosed TE units 102 can vary based on the design and/or type off-TEG network 100 in which they are used. For example, while the electrodes discussed herein are disk-shaped or round due to the use of the f-TEG network 100 predominantly discussed in this disclosure, in some embodiments, one or more of the electrodes can be shaped like squares, triangles, rhombuses, rectangles, ellipses, and so forth.

The electrodes 104, 106 and/or the wires 103 can be made of copper, e.g., a commercial copper foil, and/or other thermally and/or electrically conductive materials, e.g., steel, titanium, brass, graphite, aluminum, alloys thereof, and so forth to facilitate formation of the current path. Compounds having high thermal conductivity, such as copper, can conduct heat very well in the horizontal planes at the two sides of the device, allowing the bottom electrode 106, for example, to concentrate the body heat absorbed from the body surface of the wearer to provide the heat flux needed for a large ΔT across thermoelectric pillars 108 disposed between the two electrodes 104, 106 and spread out heat for convection to the ambient environment, as discussed in greater detail below.

The top and bottom electrodes 104, 106 of the present embodiments can be devoid or substantially devoid of ceramics, polymers, and/or other insulative materials that are common in conventional thermoelectric generators as substrates and/or external packaging layers. These soft materials have low thermal conductivity and inhibit both heat collection at the side that abuts the body and heat dissipation at the side exposed to ambient air. Previously reported flexible thermoelectric devices have commonly included these soft materials to prevent and/or eliminate oxidation or short circuit risk during use. The mushroom-like design of the TE units of present embodiments, as well as some other designs provided for or otherwise made possible by the present disclosures, eliminates the risk of either oxidation or short circuit, thereby rendering the use of these materials and/or extra layers to protect the electrodes redundant. A person skilled in the art will recognize that the top and bottom electrodes 104, 106 being substantially devoid of ceramics, polymers, and/or other insulative materials can encompass a composition of less than about 10% of such materials, a composition of less than about 5% of such materials, a composition of less than about 2% of such materials, a composition of less than about 1% of such materials, a composition of less than about 0.5% of such materials, and/or a composition of 0% of such materials. It will also be appreciated that, for the purposes of this disclosure, in some embodiments, one or more layers adjacent to the top and bottom electrodes 104, 106 may also be devoid or substantially devoid of ceramics, polymers, and/or other insulative materials. For example, in some embodiments, a thin layer of insulative soft material, e.g., less than or equal to about 2 millimeters, can be added to the top and bottom electrodes 104, 106 and/or adjacent to the top and bottom electrodes 104, 106 while remaining within the scope as being substantially devoid of ceramics, polymers, and/or other insulative materials, as this thin layer adds a negligible amount of thermal resistance.

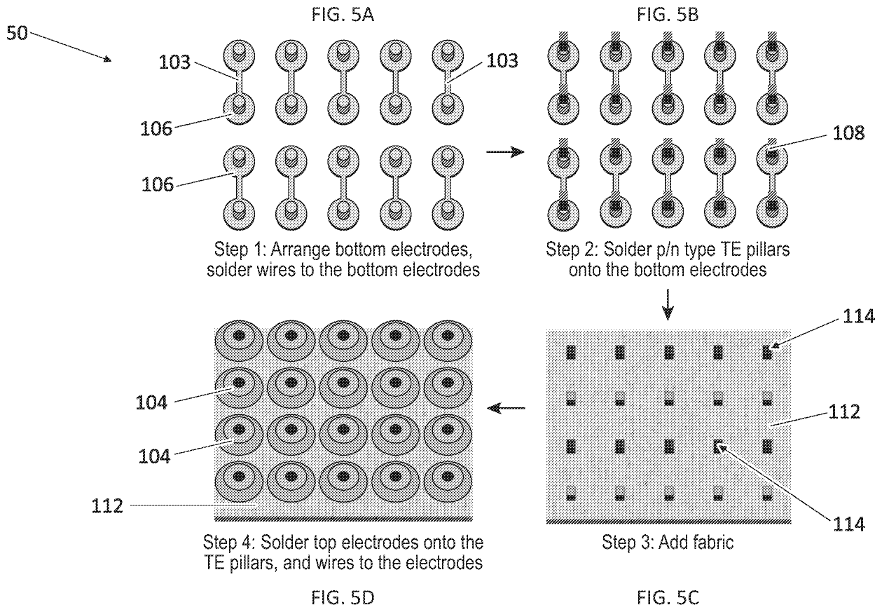

In combination with the wires 103 that are disposed between corresponding top electrodes 104 and corresponding bottom electrodes 106 of neighboring TE units 102, as shown in FIG. 1 (see also, e.g., FIGS. 5A, 5B, 6A, and 7) the top and bottom electrodes 104, 106 can be separated by a TE pillar 108, as shown, to provide a current path between the electrodes 104, 106, as well as a current path throughout the f-TEG network 100. The TE pillar 108 can be a p/n type, with, for example, p-type BiSbTe alloys and n-type BiTeSe alloys. By way of non-limiting example, in some embodiments, the TE pillars 108 can be separate pillars with current flowing in the p-type pillar in an opposite direction to the n-type pillar. The TE pillar 108 can provide for a temperature difference between the top and bottom of the TE pillar 108 to maximize power voltage output. As shown via arrows P in FIG. 2A, the bottom electrode 106 can absorb and concentrate heat from, for example, a skin surface and pass it vertically to the TE pillar 108. The heat can travel through the TE pillar 108 to the top electrode 104 where it can spread out along a surface thereof to be released into an ambient environment adjacent to the top electrode 104.

Heat conduction from the skin surface can occur vertically. In view of this, heat conduction loss and/or efficiency can be controlled by adjusting the height h₁ between the top and bottom electrodes 104, 106. For example, an increase of the height h₁ can reduce parasitic heat conduction loss between the top and bottom electrodes 104, 106. Moreover, an increase of the height h₁ to separate the top and bottom electrodes 104, 106 can increase a temperature difference across the TE pillar 108, e.g., increase ΔTᵣₑₐₗ, with the temperature difference distribution being more weighted in the TE pillar 108. In some embodiments, the top and bottom electrodes 104, 106 can include one or more spacers 110 projecting therefrom. The spacers 110 can be used to increase the height h₁ of the TE unit 102 while continuing to provide surfaces that abut the TE pillar 108 to complete the path along which heat/electricity can travel through the TE unit 102. As shown in FIG. 2A, the spacers 110 can project downward from the top electrode 104 by a length L₁ and/or upward from the bottom electrode 106 by a length L₂, with each length being measured between the flat inner surfaces 105a, 105b of each electrode, as mentioned above, and with the TE pillar 108 having a height h₂ disposed therebetween. Each of the lengths L₁, L₂ can range between 0 to h₁, while a sum of the lengths L₁ and L₂ is greater than 0 to differentiate the TE unit 102 of the present embodiments from conventional thermoelectric units. While the length L₁ can be greater than the length L₂, in some embodiments, the length L₁ can be equal to the length L₂, and/or less than the length L₂. Moreover, one or more of the length L₁ and/or length L₂ can be equal to the height h₂, less than the height h₂, and/or greater than the height h₂.

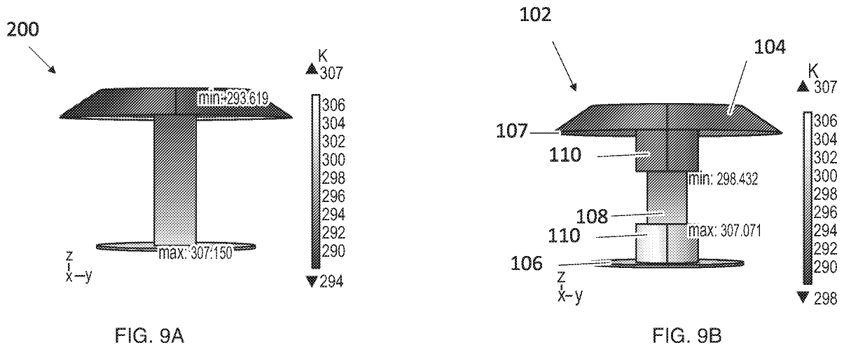

In some embodiments, the spacers 110 can project from a center portion C of the top and bottom electrodes 104, 106 to increase the thermal resistance of the thermal insulation layer between the top and the bottom electrodes 104, 106 by increasing the height h₁ while the height h₂ of the TE pillar 108 can remain unchanged. In some embodiments, the height h₂ of the TE pillar 108 is independent of the height h₁ between the top and bottom electrodes 104, 106. Use of spacers 110 to increase a height h₁ between the top and bottom electrodes 104, 106 can be preferred to conventional thermoelectrics, which use longer thermoelectric pillars, as the spacers 110 used with the TE unit 102 of the present embodiments can reduce a cost and/or a weight of the TE unit 102, as well as improve performance of the resulting f-TEG network 100, as discussed in greater detail below with respect to FIGS. 9A-9B.

The present disclosure provides for analytical models, as well as the tools to develop such analytical models, to determine optimal geometries of the TE units 102 and predict the energy-harvesting performance of the f-TEG network 100 in each thermal environment. For example, diameters and thicknesses of each of the top and bottom electrodes 104, 106 can be customized to ensure maximum thermoelectric voltage output. By way of non-limiting example, the ability of the top and bottom electrodes 104, 106 to dissipate heat to the ambient air and to absorb heat from the body, respectively, can be based on a thickness of the electrodes. In at least some embodiments, a thickness t of the bottom electrode 106 can be approximately in the range of about 50 μm to about 500 μm, or about 75 μm to about 250 μm, or about 90 μm to about 150 μm, or have a value of about 100 μm. The top electrode 104 can have a thickness that is in the same range as the bottom electrode, e.g., approximately in the range of about 50 μm to about 500 μm, or about 75 μm to about 250 μm, or about 90 μm to about 150 μm, or have a value of about 100 μm.

In some embodiments, an analytical model can be used based on the thermal resistance circuit shown in FIG. 2B to maximize output power. Specifically, A₁, A₂, A₃ represent the areas of the bottom electrode 106 the TE pillar 108, and the top electrode 104, respectively, h₁, h₂ represent the distance between the electrodes 104, 106 and the height of the TE pillar 108, respectively, t is the thickness of the top and bottom electrodes 104, 106, Rₐᵢᵣ, R_{cTE}, R_{cFB}, Rᵢₙₜ represent the contact thermal resistances at the top electrode, the top and the bottom surfaces of the TE pillar and the fabric, and between the bottom electrode and the skin, respectively. T_{ambient}, Tₛₖᵢₙ are the cold side and the hot side temperatures, respectively. hₐᵢᵣ is the heat transfer coefficient of the ambient air and hint is the effective heat transfer coefficient at the contact between the bottom electrode and the skin. κ_{TE} and κᵢₙₛ are the thermal conductivity of the TE pillar and the thermal insulation layer between the top and the bottom electrodes, respectively. Due to the high thermal conductivity of copper, the thermal resistance of the copper disks can be considered negligible, and a uniform temperature can be assumed in the copper, which can be verified by calculating the characteristic length in the annular fin model 1/√hₐᵢᵣ/κ_{copper}t (several centimeters) and COMSOL simulations.

Aspects of the analytical model can include some or all of the equations and/or tables below. The heat flow Q across the TEG is:

$$Q = \frac{{T}_{hot} - {T}_{ambient}}{( {R}_{air} + {R}_{int} + \frac{1}{\frac{1}{2 {R}_{cTE} + {R}_{TE}} + \frac{1}{2 {R}_{cFB} + {R}_{ins}}} )} \qquad ( 1 )$$

Temperature difference built up in the TE pillar at steady state ΔT:

$$Δ T = \frac{{QR}_{TE}}{( \frac{1}{2 {R}_{cTE} + {R}_{TE}} + \frac{1}{2 {R}_{cFB} + {R}_{ins}} ) ( 2 {R}_{cTE} + {R}_{TE} )} \qquad ( 2 )$$

Maximum output power with specific electrical contact resistance (R_{con}) Pₘₐₓ:

$${P}_{max} = \frac{{( Δ V )}^{2}}{4 {R}_{i}} = \frac{{( S Δ T )}^{2}}{4 ( ρ \frac{{h}_{2}}{{A}_{2}} + {R}_{con} )} \qquad ( 3 )$$

$$Let {ρ}^{′} \frac{{h}_{2}}{{A}_{2}} = ρ \frac{{h}_{2}}{{A}_{2}} + {R}_{con} and {R}_{air}^{′} = {R}_{air} + {R}_{int} = \frac{1}{{h}_{eff}^{′} {A}_{1}} \qquad ( 4 )$$

$${P}_{max} = \frac{{{S}^{2} ( {T}_{hot} - {T}_{ambtent} )}^{2}}{4 {ρ}^{′}} \frac{1}{{( \frac{2 {R}_{cTE} + {R}_{TE}}{{R}_{TE}} )}^{2} {( \frac{{R}_{air}^{′}}{2 {R}_{cTE} + {R}_{TE}} + \frac{{R}_{air}^{′}}{2 {R}_{cFB} + {R}_{ins}} + 1 )}^{2}} \frac{{A}_{2}}{{h}_{2}} = \frac{{{S}^{2} ( {T}_{hot} - {T}_{ambient} )}^{2}}{4 {ρ}^{′}} \frac{1}{{( \frac{{R}_{air}^{′}}{{R}_{TE}} + \frac{{R}_{air}^{′}}{2 {R}_{cFB} + {R}_{ins}} \cdot \frac{2 {R}_{cTE} + {R}_{TE}}{{R}_{TE}} + \frac{2 {R}_{cTE} + {R}_{TE}}{{R}_{TE}} )}^{2}} \frac{{A}_{2}}{{h}_{2}} = \frac{{{S}^{2} ( {T}_{hot} - {T}_{ambient} )}^{2}}{4 {ρ}^{′}} \frac{1}{{( \frac{{κ}_{TE} {A}_{2}}{{h}_{2} {h}_{eff}^{′} {A}_{1}} + \frac{{κ}_{ins} ( {A}_{1} - {A}_{2} ) {h}_{cFB} ( 2 {κ}_{TE} + {h}_{cTE} {h}_{2} )}{{h}_{eff}^{′} {A}_{1} ( 2 {κ}_{ins} + {h}_{cFB} {h}_{1} ) {h}_{cTE} {h}_{2}} + 1 + \frac{2 {κ}_{TE}}{{h}_{cTE} {h}_{2}} )}^{2}} \frac{{A}_{2}}{{h}_{2}} \qquad ( 5 )$$

Substitute A₂/A₁ with AR², and neglect the electrical contact resistance (R_{con}) for the ideal case:

$$\frac{{P}_{max}}{{A}_{1}} = \frac{{{S}^{2} ( {T}_{hot} - {T}_{ambient} )}^{2}}{4 ρ '} \frac{1}{{[ \frac{{κ}_{TE} AR}{{h}_{2} {h}_{eff}^{′}} + \frac{{κ}_{ins} ( 1 - {AR}^{2} ) {h}_{cFB} ( 2 {κ}_{TE} + {h}_{cTE} {h}_{2} )}{{h}_{eff}^{′} AR ( 2 {κ}_{ins} + {h}_{cFB} {h}_{1} ) {h}_{cTE} {h}_{2}} + \frac{1 + \frac{2 {κ}_{TE}}{{h}_{cTE} {h}_{2}}}{AR} ]}^{2}} \frac{1}{{h}_{2}} \qquad ( 6 )$$

To maximize

$$\frac{{P}_{max}}{{A}_{1}} ,$$

minimize the

$${[ \frac{{κ}_{TE} AR}{{h}_{2} {h}_{eff}^{′}} + \frac{{κ}_{ins} ( 1 - {AR}^{2} ) {h}_{cFB} ( 2 {κ}_{TE} + {h}_{cTE} {h}_{2} )}{{h}_{eff}^{′} AR ( 2 {κ}_{ins} + {h}_{cFB} {h}_{1} ) {h}_{cTE} {h}_{2}} + \frac{1 + \frac{2 {κ}_{TE}}{{h}_{cTE} {h}_{2}}}{AR} ]}^{2}$$

term by setting the optimal A₂/A₁ to:

$$\frac{{A}_{1}}{{A}_{2}} = \frac{1 + \frac{2 {κ}_{TE}}{{h}_{cTE} {h}_{2}} + \frac{{κ}_{ins} {h}_{cFB} ( 2 {κ}_{TE} + {h}_{cTE} {h}_{2} )}{{h}_{eff}^{′} ( 2 {κ}_{ins} + {h}_{cFB} {h}_{1} ) {h}_{cTE} {h}_{2}}}{\frac{{κ}_{TE}}{{h}_{2} {h}_{eff}^{′}} - \frac{{κ}_{ins} {h}_{cFB} ( 2 {κ}_{TE} + {h}_{cTE} {h}_{2} )}{{h}_{eff}^{′} ( 2 {κ}_{ins} + {h}_{cFB} {h}_{1} ) {h}_{cTE} {h}_{2}}} \qquad ( 7 )$$

Heat flux q (based on the area of the bottom electrode) across the TEG is independent of h₂ and h_{cTE}:

$$\frac{Q}{{A}_{1}} = q = \frac{{T}_{hot} - {T}_{ambient}}{( \frac{1}{{h}_{eff}} + \frac{1}{\frac{{A}_{1} / {A}_{2}}{\frac{2}{{h}_{cTE}} + \frac{{h}_{2}}{{κ}_{TE}}} + \frac{1 - {A}_{2} / {A}_{1}}{\frac{2}{{h}_{cFB}} + \frac{{h}_{1}}{{κ}_{ins}}}} )} = \frac{{T}_{hot} - {T}_{ambient}}{( \frac{1}{{h}_{eff}^{′}} + \frac{1}{{h}_{eff}^{′} + \frac{2}{\frac{2}{{h}_{c F B}} + \frac{{h}_{1}}{{k}_{i n s}}}} )} \qquad ( 8 )$$

$$Δ T = \frac{Q {R}_{T E}}{( \frac{1}{2 {R}_{c T E} + {R}_{T E}} + \frac{1}{2 {R}_{c A G} + {R}_{i n s}} ) ( 2 {R}_{c T E} + {R}_{T E} )} = \frac{q {A}_{1} {R}_{T E}}{( 1 + \frac{2 {R}_{c T E} + {R}_{T E}}{2 {R}_{c F B} + {R}_{i n s}} )} = q \frac{{h}_{2}}{{κ}_{TE} ( \frac{{A}_{2}}{{A}_{1}} + \frac{( 1 - \frac{{A}_{1}}{{A}_{2}} ) ( 2 \frac{1}{{h}_{cTE}} + \frac{{h}_{2}}{{κ}_{TE}} )}{2 \frac{1}{{h}_{cFB}} + \frac{{h}_{1}}{{κ}_{ins}}} )} = \frac{{T}_{hot} - {T}_{ambient}}{( \frac{1}{{h}_{eff}^{′}} + \frac{1}{{h}_{eff}^{′} + \frac{1}{\frac{2}{{h}_{cFB}} + \frac{{h}_{1}}{{k}_{ins}}}} )} \frac{{h}_{2}}{{κ}_{T E} ( \frac{{A}_{2}}{{A}_{1}} + \frac{( 1 - \frac{{A}_{2}}{{A}_{1}} ) ( 2 \frac{1}{{h}_{cTE}} + \frac{{h}_{2}}{{κ}_{TE}} )}{2 \frac{1}{{h}_{cFB}} + \frac{{h}_{1}}{{κ}_{ins}}} )} = \frac{{T}_{hot} - {T}_{a m b ient}}{( \frac{1}{{h}_{eff}^{′}} + \frac{1}{{h}_{eff}^{′} + \frac{2}{\frac{2}{{h}_{cFB}} + \frac{{h}_{1}}{{k}_{ins}}}} )} \cdot \frac{1}{( 1 + \frac{2 {k}_{TE}}{{h}_{2} {h}_{cTE}} ) ( {h}_{eff}^{′} + \frac{2}{\frac{2}{{h}_{c F B}} + \frac{{h}_{1}}{{k}_{i n s}}} )} = \frac{{T}_{hot} - {T}_{ambient}}{( \frac{2}{{h}_{eff}^{′} ( \frac{2}{{h}_{cFB}} + \frac{{h}_{1}}{{k}_{ins}} )} + 2 ) ( 1 + \frac{2 {k}_{TE}}{{h}_{2} {h}_{cTE}} )}$$

where the physical quantities are summarized in Table 1.

TABLE 1
Physical quantities used in the heat transfer model

| Physical quantity | Symbol | Value | |
|---|---|---|---|
| Hot side temperature of TE module | Tₕₒₜ | 34° | C. |
| (skin temperature) | | | |
| Ambient temperature | T_{ambient} | 15° | C. |
| Thermal conductivity of the TE pillars | κ_{TE} | 1.4 | W/(m · K) |
| (the average of n and p type materials) | | | |
| Thermal conductivity of the insulation | κᵢₙₛ | 0.03 W/(m · K) | |
| layer (the fabric matrix) | | Ideal case: | |
| | | 0 W/(m · K) | |
| Area of a top electrode | A₃ | π(9 mm)²/4 | |
| Area of a TE pillar's cross-section | A₂ | 1.55 mm × 1.55 mm | |
| Area of a bottom electrode | A₁ | π(6 mm)²/4 | |
| Convective heat transfer coefficient | hₐᵢᵣ | Input variable | |
| of the ambient air | | | |
| Total thickness of the device | h₁ | 6 | mm |

| | | |
|---|---|---|
| TE pillar height | h₂ | Input variable |
| Effective heat transfer coefficient | h_{eff} | hₐᵢᵣA₃/A₁ |
| at the cold side considering extended | | |
| heat dissipation area | | |
| Thermal contact conductance | hᵢₙₜ | 100 W/(m² · K) |
| coefficient at the interface between | | Ideal case: |
| the bottom electrode and human skin | | 1e9 W/(m² · K) |
| Thermal contact resistance between | Rᵢₙₜ | 1/(hᵢₙₜA₁) |
| the bottom electrode and human skin | | |
| Effective heat transfer coefficient | h′_{eff} | 1/(1/h_{eff} + 1/hᵢₙₜ) |
| considering extended heat dissipation | | |
| area and thermal contact resistance Rᵢₙₜ | | |
| Thermal contact conductance | h_{cTE} | 4120 W/(m² · K) |
| coefficient at the interface between the | | Ideal case: |
| electrode and the TE pillar | | 1e9 W/(m² · K) |
| Thermal contact conductance coefficient | h_{cFB} | 1e9 W/(m² · K) |
| at the interface between the electrode | | |
| and the fabric | | |
| Thermal resistance in the insulation | Rᵢₙₛ | h₁/κᵢₙₛ/(A₁ − A₂) |
| layer | | |
| Thermal resistance in the TE pillar | R_{TE} | h₂/(κ_{TE}A₂) |
| Thermal resistance in the air | Rₐᵢᵣ | 1/(hₐᵢᵣA₃) |
| Thermal contact resistance at the | R_{cTE} | 1/(h_{cTE}A₂) |
| interface between the electrode and | | |
| the TE pillar | | |
| Thermal contact resistance at the | R_{cFB} | 1/h_{cFB}/(A₁ − A₂) |
| interface between the electrode and | | |
| the fabric | | |
| Internal electrical resistance | Rᵢ | ρh₂/A₂ |
| Seebeck coefficient of the TE pillars | S | 205e−6 V/K |
| (the average of n and p type) | | |
| Electrical resistivity of the TE pillars | ρ | 8.3e−6 Ω m |
| (the average of n and p type) | | |

It will be appreciated that the convective heat transfer coefficient for air flow hₐᵢᵣ can be approximated to:

$${h}_{a i r} = \{ \begin{matrix}14.41 \times {v}^{0.358} ( 0.02 < v \leq 2 m / s ) \\ 12.12 - 1.16 \times v + 11.6 \times {v}^{0.5} ( 2 m / s < v < 20 m / s )\end{matrix} \qquad ( 9 )$$

where v is the windspeed.

Heat absorption and dissipation via the electrodes can be based, at least in part, on a size of the top and bottom electrodes of the TE units 102. The top electrode 104 can be responsible to facilitate heat dissipation at the cold side, while the bottom electrode 106 can accommodate heat absorption at the hot side. The top electrode can be larger than the bottom electrode 106, as shown, with the area A₃ of the top electrode 104 being larger than the area A₁ of the bottom electrode. It will be appreciated that in some embodiments, the bottom electrode can be larger or the electrodes can be of equal size, e.g., A₃ being equal or substantially equal to A₁. By way of non-limiting example, a diameter of the top electrode 104 can be in a range from approximately 5 millimeters to about 15 millimeters, or be about nine (9) millimeters, a diameter of the bottom electrode 106 can be in a range from approximately 3 millimeters to about 10 millimeters, or be about six (6) millimeters, and a length of the TE pillar 108 can be in a range from approximately 0.5 millimeters to about 8 millimeters, or be determined by the pillar height h₂ and the thermal environment as part of the inverse heat concentration ratio (A₂/A₁), as discussed below. In view of area calculations for such an example, a person skilled in the art will recognize that an area for the electrodes having a diameter of about 9 millimeters for the top electrode 104 and a diameter of about 6 millimeters for the bottom electrode 106, as discussed above, can be approximately in a range of about 971 to about 20.25n. Further, a person skilled in the art will appreciate other diameters, and ratios between the diameters of the top and bottom electrodes 104, 106, are possible without departing from the spirit of the present disclosure. For example, a ratio of the area A₃ of the top electrode 104 to the area A₁ of the bottom electrode 106 can be approximately in a range of about 1≤A₃/A₁<25. By way of non-limiting example, in some embodiments a value of A₃/A₁ can be about 2.25.

Sizing of the electrodes can also accommodate large bending of one or both of the top and bottom electrodes 104, 106. In some embodiments, one or more of the electrodes can impart flexibility to the f-TEG network 100. For example, as shown, the edges 107 of the top electrode 104 can be chamfered to prevent cuts and achieve a more premium look and feel. Moreover, as shown in FIG. 2A, each electrode 104, 106 can include a U-shape vertical cross-section which can allow it to serve as a spacer, heat concentrator, and/or spreader, in addition to providing performance-enhancing electrically conductive properties.

Generally, a larger height, or thickness, h₁ between the top and bottom electrodes 104, 106 in the f-TEG network 100 and larger thermoelectric pillar heights can lead to a bigger temperature difference in the pillars to benefit the output thermoelectric voltage. It will be appreciated that the benefit of maximum thermoelectric voltage output can, and often should, be balanced against good wearability and flexibility of the f-TEG network 100. For example, using the analytical model, a thickness h₁ of the f-TEG network 100 that is about 6 millimeters can provide good wearability and flexibility while having a large power output. FIGS. 2C-2D can illustrate calculated maximum output power density (maximum output power divided by the total area of top electrodes NA3 where N is the number of units) (FIG. 2C) and optimal area ratio (the cross-section area of the thermoelectric pillar to the area of the bottom electrode) (FIG. 2D) can be measured as a function of thermoelectric (TE) pillar height.

As shown in FIGS. 2C-2D, maximum power output can be measured at three different levels of heat dissipation at the cold side, e.g., top electrode 104, when maximizing the output power density in the analytical model. For example, as shown, the curves can represent three different cases of heat transfer coefficients for a top electrode 104 under convection at an external temperature of about 15° C. and a bottom electrode 106 of about 34° C., with a total thickness of the device h₁ of about 6 mm and a supporting fabric 112, which is discussed in greater detail below, having a thermal conductivity of about 0.03 W/mK. More particularly, the first case, (A), has a heat transfer coefficient of, 8 W/m²K, the second case, (B), has a heat transfer coefficient of 16 W/m²K, and the third case, (C), has a heat transfer coefficient of 32 W/m²K. The calculated maximum output power density gradually increases as heights h₂ of the TE pillar 108 increase along a given heat transfer coefficient, with higher heat transfer coefficient values having greater calculated maximum output power densities.

Moreover, as shown in cases (A)-(C), an output power density of the top electrode 104 can increase proportionally with an increase in a heat transfer coefficient thereof across increasing values of height h₂. With respect to FIG. 2D, the distribution density of the units can vary at an optimal area ratio of a cross-section of the TE pillar 108 to the bottom electrode A₂/A₁, e.g., the inverse heat concentration ratio, which can increase or decrease based on the height h₂ of the TE pillar 108. It will be appreciated that while the maximum output power density in FIG. 2C can depend on the temperatures of the hot and the cold sides, the best area ratio A₂/A₁, shown in FIG. 2D, may not, and it may be uniquely determined by the total thickness h₁, the thermoelectric pillar height h₂, thermal properties of the materials used in the f-TEG network 100, and/or heat transfer coefficients at the surfaces.

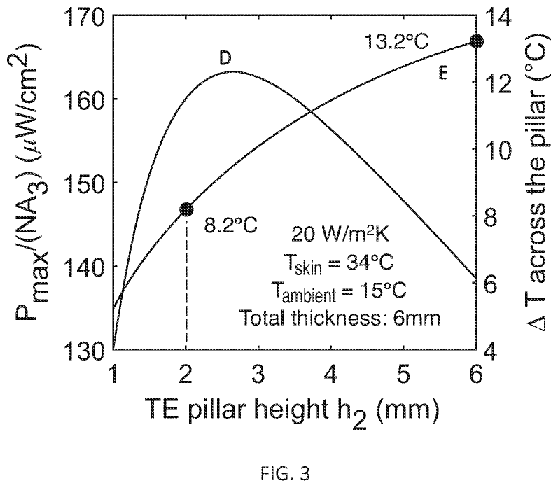

Similarly, if a ratio of A₂/A₁, e.g., approximately in a range of about 0.01<A₂/A₁<0.5, is fixed instead of h₂, an optimal height h₂ of the TE pillar 108 can be determined analytically, as shown by curves (D) and (E) in FIG. 3. As shown by curve (D), the increase in a theoretical maximum output power density having ideal thermal insulation can be less evident when the pillar height h₂ exceeds 2 millimeters. Further, the taller the thermoelectric pillars 108 are, the greater the temperature change is across the pillar, as shown by curve (E), though increasing values of h₂ do not necessarily correspond to larger output power densities, as shown. It will be appreciated that the taller pillars may be more prone to fracture because of potentially larger bending moment, and further, such pillars may be more expensive because of increased materials cost. In some embodiments, the TE pillars 108 can be about 1.9 mm (height)×about 1.55 mm×about 1.55 mm, such that the A₂/A₁ area ratio is about 0.085 (the optimal value at h₁=6 mm, a wind speed approximately in the range of about 3 m/s to about 4 m/s from the analytical model).

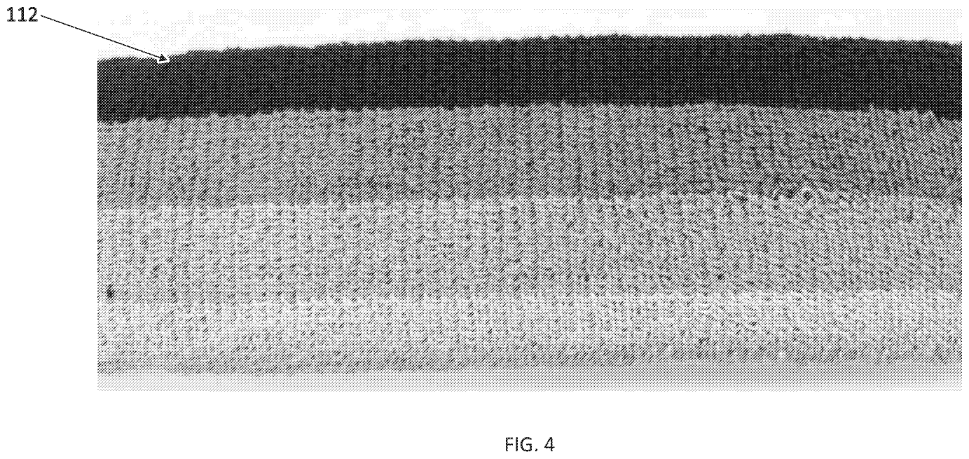

In some embodiments, the f-TEG network 100 of the present embodiments can be associated with a fabric 112. Adding the fabric 112 can help eliminate the convection between the top electrode 104 and the bottom electrodes 106. A size and/or type of fabric used can vary. For example, as shown in FIG. 4, the fabric 112 can be a commercial headband with a thermal conductivity ˜0.03 W/mK. The fabric 112 can be made from one or more of cotton, polyester fiber, diene plastic fiber, spandex, and so forth, of varying thickness. The low thermal conductivity of the fabric 112 and its loose contact with the rest of the thermoelectric unit 102 can reduce the heat flux parallel to the heat flux through the thermoelectric pillars 108, which can be beneficial for absorption of heat from the skin surface as a lower heat flux can result in heat absorption over a larger surface area. The fabric 112 can support the f-TEG network 100 of thermoelectric units 102, protect the thermoelectric pillars 108 from sudden impacts, and/or absorb sweat to prevent short circuit and/or provide added comfort in wearing. For the purposes of this disclosure, while a headband is shown, a person skilled in the art will recognize that the embodiment is merely exemplary, and can include any device that can be worn by a human or other animal, with the f-TEG network 100 capable of being associated with one or more of undergarments, compression sleeves, t-shirts, and other garments, clothing, textiles, and so forth.

FIGS. 5A-5D illustrate an example embodiment of a fabrication process 50 of the f TEG device 10 in which the f-TEG 100 includes the fabric 112 associated therewith. For example, a plurality of bottom electrodes 106 can be arranged in a pattern to allow for maximum coverage of the surface area of the skin. The pattern in which the bottom electrodes 106 are arranged can be determined, for instance, by the analytical model discussed above. For example, as shown in FIG. 5A, the bottom electrodes 106 can be uniformly distributed and arranged in rows with the bottom electrodes 106 in neighboring rows being connected by the wires 103. Connections between the bottom electrodes 106 and the wires 103 can be formed by soldering or another form of integrated attachment.

Once the soldering is complete, the TE pillars 108 can be soldered, disposed in, and/or otherwise associated with the bottom electrodes 106. As shown in FIG. 5B, the TE pillars 108 can protrude from the spacers 110 of the bottom electrodes 106 to allow heat to travel therethrough. In some embodiments, the fabric 112 can be added to the pillars 108. As shown in FIG. 5C, the fabric 112 can include a series of openings 114 formed therein to receive the TE pillars 108 therethrough. The openings 114 can be pre-formed and/or the fabric can be produced in such a manner that the openings 114 can be formed by manipulating the fabric to create a sufficient-sized opening to receive the pillars 108. Alternatively, or additionally, the fabric 112 can be loosely knitted to allow the pillars 108 to pass therethrough. Once the fabric 112 is added, the top electrodes 104 can be soldered to the TE pillars 108 and the wires 103 can be soldered to the top electrodes 104, as shown in FIG. 5D. The electrodes 104 can include spacers like the spacers 110, which can be involved in the attachment between the pillars 108 and the top electrodes 104. The instantly disclosed fabrication process is scalable, low-cost, and high-performing output can be readily achieved.

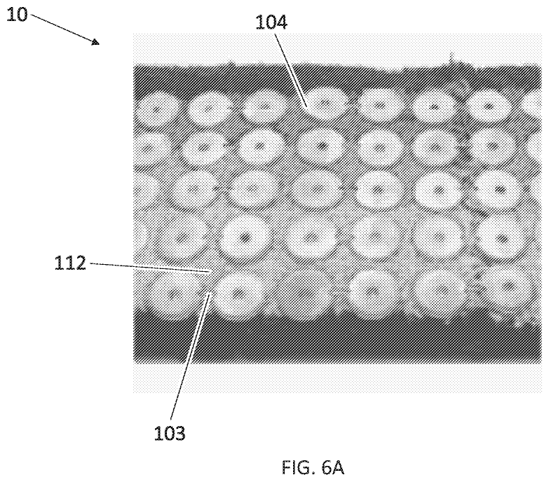

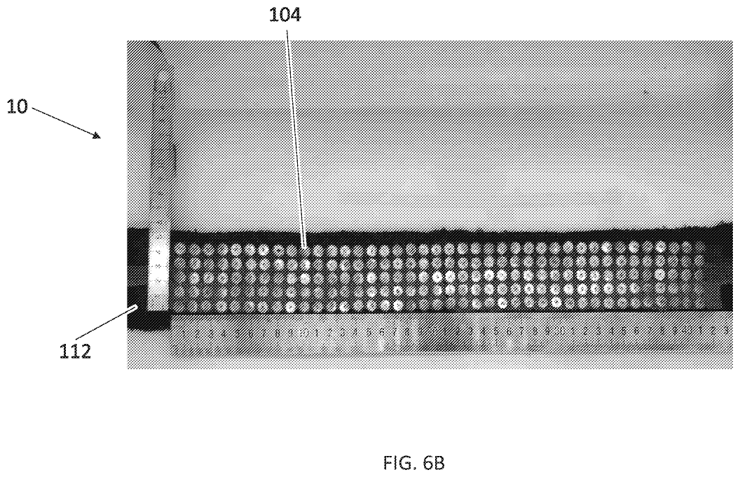

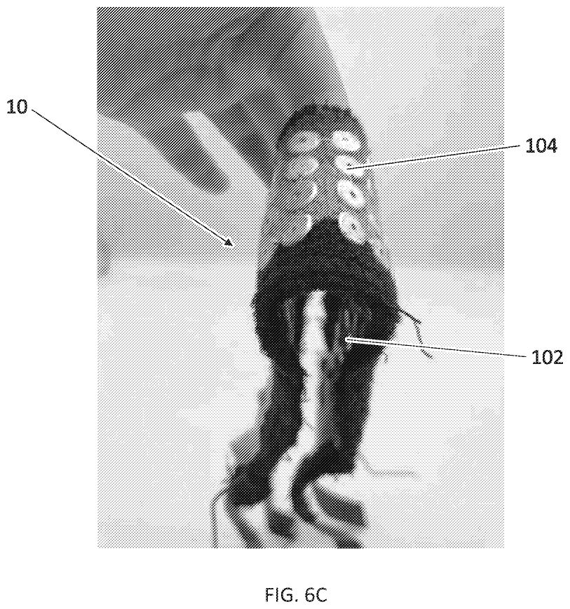

An example embodiment of the f-TEG device 10 following the fabrication process 50 is shown in FIGS. 6A-6C. As shown in FIG. 6A, for example, an orientation of the top electrodes 104 and/or the soldering pattern of the wires 103 can resemble the pattern of the bottom electrodes 106, though, in some embodiments, the pattern can be different. FIG. 6B illustrates an example embodiment of a distribution density of TE units 102 throughout the f-TEG device 10. As shown, one hundred pairs of TE units 102 can be uniformly distributed in an area of ˜200 cm² (˜4.8 cm×˜41.5 cm), though the distribution can vary based on one or more of the factors discussed above or otherwise appreciated by those skilled in the art in view of the present disclosures. A typical distribution density that can keep a good balance between performance and wearability for a headband, such as one that is shown in FIG. 6C, can be about 100 cm² per 50 pairs. Alternatively, or additionally, in some embodiments, the distribution can be based on maintenance of a desired flexibility of the f-TEG network 100 of the f-TEG device 10. As shown in FIG. 6C, the uniform distribution of the f-TEG network 100 of FIG. 6B with fabric 112 can result in a wearable f-TEG device 10 with such flexibility that it can be bent upon itself at a bending radius in approximately a range of about 1 centimeter to about 10 centimeters, which can be worn as a headband or around another part of the wearer's body. The electrodes 106 can be the portion worn against the body and the electrodes 104 can be facing an outside, ambient environment.

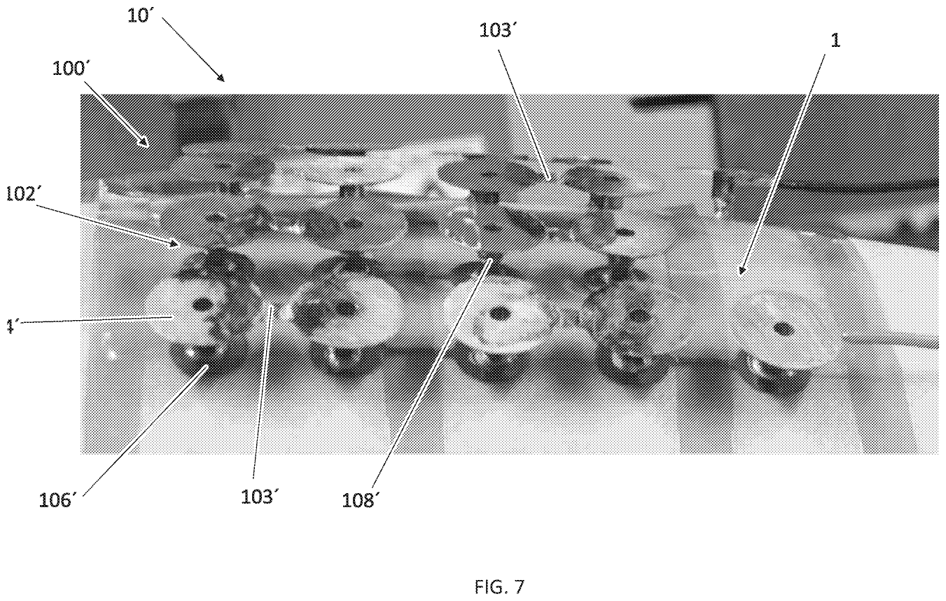

In some embodiments, the f-TEG network of the present embodiments can be worn as a standalone f-TEG device 10′. As shown in FIG. 7, the f-TEG network 100′ can include a plurality of TE units 102′ linked by copper wires 103′ that are disposed directly on human skin to allow direct contact between the bottom electrode 106′ and the skin surface 1 while the top electrode 104′ is exposed to the ambient environment. Unlike conventional TE devices, which include an insulative layer between the skin and the electrode, direct contact with the skin can allow the f-TEG network 100 to maximize heat absorption from the body, which maximizes efficiency of the f-TEG network 100.

Power Generation Performance of the f-TEG Device

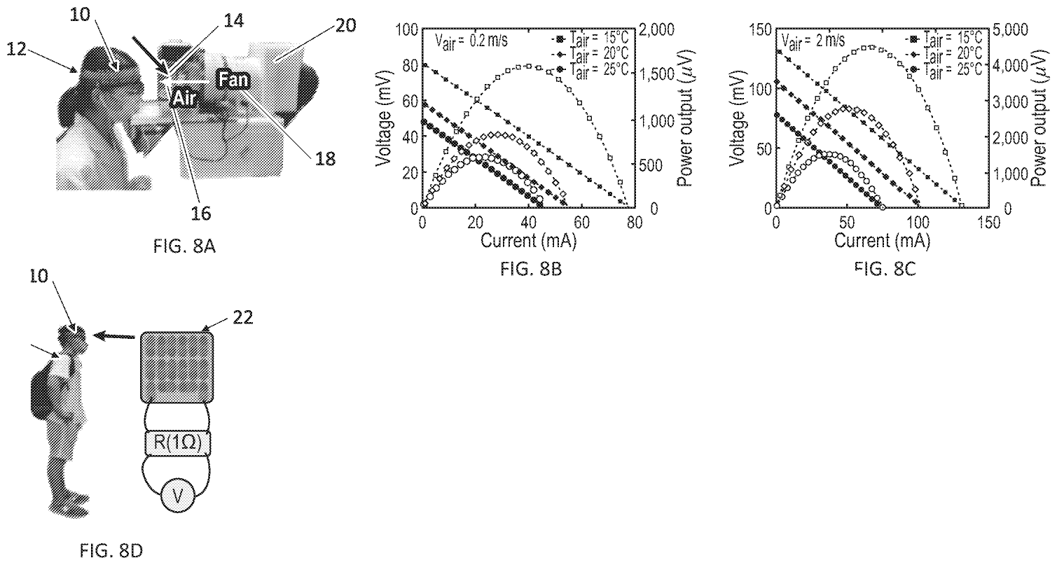

Indoor and outdoor testing can be performed to test the energy-harvesting performance of the f-TEG device 10. FIG. 8A illustrates an example embodiment of a setup for indoor testing. As shown, a subject 12 wearing the f-TEG device 10 can sit in front of an air chamber 14 with the f-TEG device 10 on the forehead facing an air outlet 16 thereof. The airflow with tunable temperature and velocity can be generated by a fan 18 and a heating/refrigerated circulator 20 with a heat exchanger. The wind speed and the air temperature at an outlet of the air chamber 14 can be measured by an anemometer and a thermocouple placed near the outlet. In indoor testing, the typical power generation of an f-TEG device 10 having fifty pairs of thermoelectric units 102 thereon (which is half of the density of the device described in FIG. 6B), as a function of sweeping current is given in FIG. 8B (at a wind speed of about 0.2 m/s) and FIG. 8C (at a wind speed of about 2 m/s). As shown, power output can increase at higher wind speeds of about 2 m/s as compared to wind speeds of about 0.2 m/s at all ambient temperatures. The output power density can increase with the distribution density of the TE units while finding a balance between high output power density and good flexibility. The current sweep, the output voltage, and temperature measurements can be programmed using a program like LABVIEW and data can be collected by, for example, a Keithley 2450 multimeter, a NI compact DAQ chassis (cDAQ-9185), and NI-9214 temperature input module. Three thermocouples can used to measure the hot side temperature Tₕ, the cold side temperature Tc of the f-TEG device 10, and the air temperature Tₐᵢᵣ at the chamber's outlet 16. An anemometer (e.g., Testo 405i) can be located ˜6 cm away from the chamber's outlet to measure the wind speed. The I-V curve of the LED can be recorded by, for example, a Keithley 2400 multimeter.

Moreover, the measured nominal maximum output power densities of the f-TEG device 10 (based on the device area) can be in approximately a range of about 5 μW/cm² to about 60 μW/cm². In some embodiments, such as when used on human skin, the measured nominal maximum output power density of the f-TEG device 10 can be about 6.3 μW/cm² at a wind speed of about 0.2 m/s, and an ambient temperature of about 25° C., and about 48 μW/cm² at a wind speed of about 2 m/s, and an ambient temperature of about 15° C. The distribution density of the TE units 102 can vary to meet different power output density and flexibility needs, and a more compact design can lead to an even higher output power density, albeit with increased stiffness of the f-TEG device 10. The upper limit of the maximum output power density at the extreme packing density can be calculated based on the total area of top electrodes. For example, it can vary from about 10 μW/cm² (vₐᵢᵣ=0.2 m/s, Tₐᵢᵣ=25° C.) to about 76 μW/cm² (vₐᵢᵣ=2 m/s, Tₐᵢᵣ=15° C.).

In outdoor testing, the subject 12 wearing the f-TEG device 10 can carry a portable data logger 22, e.g., disposed in a backpack, while walking and/or running outdoors. Like in indoor testing, two thermocouples can be attached to the top electrode 104, e.g., the cold side, and the bottom electrode 106, e.g., the hot side, recording temperatures. The f-TEG device 10 can be connected to an external resistance of 1 Ohm for impedances matching, and the output voltage can be monitored by a data logger (e.g., FLUKE 3000FC). Two thermocouples can be attached to the top electrode 104 and the bottom electrode 106 in the f-TEG device 10 recording temperatures. The outdoor temperature can be read from a digital thermometer (e.g., Xiaomi LYWSD02MMC). The running speed can be estimated using the total running distance and the running time.

An f-TEG device 10 having fifty pairs of TE units 102 can generate an output power of up to about 1.2 mW during an outdoor jog at night at an outdoor temperature of about 25° C. (estimated running speed: about 2.5 m/s), which can be comparable to the indoor results discussed above at Tₐᵢᵣ=25° C. and vₐᵢᵣ=2 m/s. For example, despite fluctuations in the power output curve, the average power output can increase with time due to better heat dissipation at the cold side of the f-TEG device 10 and potentially increased metabolic heat at the hot side during running. In some embodiments, the f-TEG device 10 can generate sufficient power to power a commercial LED to illuminate a paper for reading in a completely dark room at about 16.5° C. without an external heat sink or forced convection at the cold side of the f-TEG device 10. Hence, the f-TEG device 10 can be readily integrated with commercial headlamps to light the way for outdoor activities like running, hiking, and camping at night. Moreover, given that many IoT sensors typically use less power than LEDs (LEDs usually demand a milliwatt-level power input), the f-TEG device 10 can have even more promising IoT applications.

The airflow against the headband of the f-TEG device 10, as well as the contact between the headband and the skin, can keep changing due, at least in part, to the motion, which may lead to some uncertainties in the measured data. However, both the hot side temperature and the cold side temperature decrease at the beginning can be due to enhanced convection at the top surface, while the hot side temperature can rise later during the exercise. Moreover, in outdoor testing the fabric 12 of the f-TEG device 10 can also hold up well against sweat, with wetting the headband being performed to demonstrate robustness of the f-TEG device 10 with no short circuit observed in the wet state. In fact, in some embodiments, power generation performance of the f-TEG device 10 in the wet state, e.g., when the fabric 12 is moist, can be superior to performance in the dry state.

To better elucidate the significance of the thermal design for the enhancement off-TEG device 10 power generation performance, a quantitative comparison of the maximum output power density and the temperature difference across the thermoelectric pillar 108 between the TE unit 102 of the f-TEG device 10 of the present embodiments having spacers 110 (FIG. 9B), and a conventional design having a longer pillar with no spacers (FIG. 9A), can be performed by using both the analytical model and COMSOL simulations. FIGS. 9A-9B illustrate an example of such a quantitative comparison when a total thickness of the f-TEG device 10 is fixed, e.g., 6 mm, the bottom electrode 106 is at about 34° C., and the upper surface of the top electrode 104 is under convection at an external temperature of about 15° C. and a heat transfer coefficient of about 20 W/m²K (roughly equivalent to the condition when the wind speed is approximately in the range of about 2 m/s to about 3 m/s). An ideal case with negligible thermal contact resistances at the interfaces and perfect insulation around the thermoelectric pillar 108 between the two electrodes 104, 106 can be studied to obtain the theoretical maximum values when the materials of insulation layer and adhesives are ultimately optimized. The calculated temperature difference across the thermoelectric pillar 108 (ΔT=8.2° C. at h₂=2 mm and ΔT=13.2° C. at h₂=6 mm) can match the COMSOL simulation results (ΔT=8.6° C. in FIG. 9B and ΔT=13.5° C. in FIG. 9A). Though a larger temperature difference can be obtained with increasing h₂, the maximum output power density may not increase with h₂ when the areas of thermoelectric pillar 108 cross-section and electrodes are set. As shown, the mushroom-like design with spacers (h₂=2 mm, FIG. 9B) has a higher maximum output power density than the design without spacers (h₂=5.9 mm, FIG. 9A) in the ideal case. These findings can explain why the mushroom-like f-TEG device 10 of the present embodiments can exceed, in some embodiments by about 3 times to about 5 times, previously reported conventional f-TEGs in terms of output power density based on the total device area (including the space between copper disks) on human skin without using an external heat sink and reduces cost and weight of thermoelectric materials at the same time. The design of FIG. 9B can have an even higher maximum output power density than conventional designs in which a hydrogel or a phase-change material is placed inside the cavity in the electrodes facing the ambient air, which further enhances the heat dissipation at the heat sink and therefore increases the temperature difference across the thermoelectric pillar of the conventional design. A person skilled in the art, in view of the present disclosures, will understand that these types of results will occur in other configurations that are not necessarily mushroom-like, with instead the more important aspects that lead to these results being enhanced heat concentration at the heat collection (hot) side, enhanced heat dissipation at the heat sink (cold) side, and reduced the heat leakage that bypass the TE pillar 108.

A summary of bulk-based wearable f-TEGs' output power density Pₘₐₓ (based on device area) on the human body without external heat sinks is provided for in Table 2 below. While the present disclosure can focus on power generation, it will be appreciated that these devices can also be used for personalized cooling. The low-cost and high-performance f-TEG devices 10 can offer an even wider prospect for low-power monitors or control systems in the domains of healthcare, agriculture, transportation, industrial automation, the Internet of Things (IoT), aerospace engineering, and many more.

TABLE 2
A summary of bulk-based wearable f-TEGs' output power density
Pₘₐₓ (based on device area) on the human body without external heat sinks.

| | TE pillar | Ambient temperature | Pₘₐₓ | Heat | |
|---|---|---|---|---|---|
| TE material | dimension | and wind speed | (μW/cm²) | source | Source |
| Commercial TE alloys | 5 mm (H) × | 22° C., natural convection | 4.5 | human skin | Prior Art |
| (TEC1-07101, Jiangxi | 1 mm × 1 | 22° C., vₐᵢᵣ = 1.4 m/s | 10.7 | (32° C.) | |
| Thermonamic | mm | | | | |
| Electronics Corp. Ltd.) | | | | | |
| n: Bi_{0.5}Sb_{1.5}Te₃, | 2.5 mm (H) × | 25° C., natural convection | 2.28 | artificial | Prior Art |
| p: Bi₂Te_{2.7}Se_{0.3} | 1 mm × 1 mm | 25° C., vₐᵢᵣ = 1 m/s | 4.88 | arm | |
| | | 25° C., vₐᵢᵣ = 2 m/s | 6.2 | (33.9° C.) | |
| n: Bi₂Te₃ | 0.5 mm | 15° C., outdoor, | ~0.75** (an | human | Prior Art |
| p: Sb₂Te₃ | (H), ~1.8** | wind speed not | output power | skin | |
| | mm (diameter) | mentioned | of 3 μW) | | |
| n: Bi₂Te₃ | 1.5 mm (H) × | Room temperature, | 0.516 | human | Prior Art |
| p: Sb₂Te₃ | 1 mm × 1 mm | natural convection | | skin | |
| n: Mg_{3.2}Bi_{1.498}Sb_{0.5} Te_{0.002} | 2.5 mm × 2.5 | 16° C., vₐᵢᵣ = 1.1 m/s | 13.6 | human | Prior Art |
| p: Bi_{0.4}Sb_{1.6}Te₃ | mm × 2.5 mm | | | skin | |
| Commercial BiTeSe | 1.9 mm (H) × | 25° C., natural convection | 6.0 | human | This |
| (n) and BiSbTe (p) | 1.55 mm × | 25° C., vₐᵢᵣ = 0.2 m/s | 6.3 | skin | disclosure |
| alloys | 1.55 mm | 25° C., vₐᵢᵣ = 1 m/s | 14.2 | (31~35° C.) | |
| (Guangdong Fuxin | | 25° C., vₐᵢᵣ = 2 m/s | 16.8 | | |
| Technology Co., Ltd.) | | 22° C., natural convection | 9.7 | | |
| | | 22° C., vₐᵢᵣ = 0.2 m/s | 10 | | |
| | | 15° C., vₐᵢᵣ = 0.2 m/s | 16 | | |
| | | 15° C., vₐᵢᵣ = 1 m/s | 39.8 | | |
| | | 15° C., vₐᵢᵣ = 2 m/s | 48 | | |

**Estimated from a figure with a scale bar because the detailed numbers are not given in the publication.

The mechanical performance of the f-TEG devices 10 during use can be further studied by simulating the thermoelectric units 102 (h₂=2 mm with spacers and h₂=5.9 mm without spacers, with the same total unit thickness and areas of the top and the bottom electrodes) in both shear mode and off-axis compression mode. Conventional Bi₂Te₃-based thermoelectric materials have been known to have poor mechanical properties and are subject to fracture. It has been observed that Bi₂Te₃ can easily cleave along the (00l) plane. A previous density functional theory study has found that the weak van der Waals interactions between the Tel atoms dominate the failure process of crystalline Bi₂Te₃, leading to a very low ideal shear strength of about 0.19 GPa that is only approximately in the range of about 0.4% to about 2% of its bulk Young's modulus (approximately in the range of about 10 GPa to about 50 GPa). The mechanical weak point in the TEGs can be the bonding interface between the metallization layer (e.g., nickel) and the thermoelectric material (typical bonding strength approximately in the range of about 10 MPa to about 30 MPa). To quantitatively evaluate the mechanical robustness of the f-TEG device 10, the maximum shear stress (half of the difference between the maximum and the minimum principal stresses σ₁ and σ₃) can be simulated in the thermoelectric pillar as a function of the force applied to one side of the chamfered edge 107 of the top electrode 104 along the Z− direction (compression mode) and the X+ direction (shear mode) with the bottom electrode 106 being fixed in COMSOL. A summary of the material properties used in the COMSOL Heat Transfer and Solid Mechanics simulation can be found in Table 3 below.

TABLE 3
Material properties used in the COMSOL Heat
Transfer and Solid Mechanics simulation.

| | Bi₂Te₃ | | Copper | |
|---|---|---|---|---|
| Heat capacity at constant | 154 J/(kg · K) | | 385 J/(kg · K) | |
| pressure | | | | |
| Density | 7700 | kg/m³ | 8960 | kg/m³ |
| Thermal conductivity | 1.40 | W/(m · K) | 400 | W/(m · K) |
| Young's modulus | 50e9 | Pa | 110e9 | Pa |

| | | |
|---|---|---|
| Poisson's ratio | 0.241 | 0.35 |

The largest maximum shear stress in the TE pillar 108 can occur near the top and the bottom edges 103, which can be attributed to the geometry discontinuity between the electrodes 104, 106 and the thermoelectric pillar TE 108 that can cause a local increase of stress. For example, most instances of failure can happen near the contacts in experiments (e.g., the nickel layer detaches from the thermoelectric material). In the off-axis compression mode, e.g., force applied along the Z-direction, the maximum shear stress in the TE unit 102 having a shorter TE pillar 108 due to the presence of spacers 110 (FIG. 9B) can be smaller than that in the taller thermoelectric pillar without spacers (FIG. 9A). The distribution of the maximum shear stress along one side can suggest that the stress concentration near the top edges is more considerable in the conventional design using a taller thermoelectric pillar (FIG. 9A) than the edge 107 of the TE unit 102 of the present embodiments (FIG. 9B) in compression mode. When the TE pillar 108 is subject to shear (force applied along the X+ direction), greater amounts of stress are observed near the bottom edges of the thermoelectric pillar 108 in FIG. 9B than in the conventional design (FIG. 9A). The above suggests that, when it comes to the conventional approach, the spacer design of the present embodiments, at the same total thickness, can be beneficial to the strength of the f-TEG device 10 under compression, but not so in the shear mode.

In some embodiments, mechanical performance of the f-TEG device 10 can be further improved by optimizing the shape of the copper spacers 110, and the contacts between the top and bottom electrodes 104, 106 and the thermoelectric pillar 108 to reduce the stress concentration (e.g., include gradual transitions, chamfer the sharp corners of the pillars). For example, a normalized electrical resistance against bending radius and bending cycles of the f-TEG device 10 can stay the same after being bent up to 10,000 times, which indicates that the device 10 should be able to sustain wear after bending more than 10,000 times.

### Experimental Procedures

### Characterization of the Thermoelectric Materials

The composition analysis of the thermoelectric materials (e.g., n-type BiTeSe and p-type BiSbTe alloys from Guangdong Fuxin Technology Co., Ltd.) can be carried out using the electronic probe micro-analysis (e.g., EPMA, JEOL-JXA-8100). Samples can be cut into pieces of about 3 mm×about 3 mm×about 13 mm for electrical properties measurements. Seebeck coefficient and electrical resistivity can be measured in a helium atmosphere under a pressure of about 0.01 MPa from about room temperature to about 250° C. (e.g., CTA-3S, Beijing Cryoall Science and Technology Co., Ltd). Thermal conductivity (κ) can be calculated by κ=DCₚρ, where the thermal diffusivity (D) and the specific heat (Cₚ) can be measured by the laser flash method (e.g., LFA 467, Netzsch) using samples with the dimensions of about 6 mm×about 6 mm×about 1 mm. Density (ρ) can be determined by the Archimedean method.

Examples of the above-described embodiments can include the following:

1. A flexible thermoelectric generator device, comprising:
a thermoelectric generator network that includes a first thermoelectric unit comprising:
   a top electrode having a first spacer extending a first length therefrom, the top electrode being defined by an area A₃;
   a bottom electrode having a second spacer extending a second length therefrom towards the first spacer, the bottom electrode being defined by an area A₁ and being a distance h₁ apart from the top electrode; and
   a pillar disposed between the first spacer and the second spacer to separate the first spacer from the second spacer, the pillar being configured to transmit thermal energy between the top and bottom electrodes, the pillar being defined by an area A₂ and a height h₂ that is independent of the distance h₁;
   wherein the area A₃ is larger than the area A₁, and
   wherein a ratio of the areas A₂/A₁ is based on the height h₂ of the pillar or the height h₂ of the pillar is based on the ratio of the areas A₂/A₁.
      2. The device of claim 1, wherein a temperature difference defined across the distance h₁ is lower than a temperature difference defined across the distance h₁ in the absence of the first spacer or the second spacer.
      3. The device of claim 1 or claim 2, wherein the height h₂ of the pillar is smaller than the distance h₁.
      4. The device of any of claims 1 to 3, wherein a ratio of the area A₃ to the area A₁ is approximately in a range of about 1 to about 25.
      5. The device of any of claims 1 to 4, wherein the top and bottom electrodes are substantially devoid of an insulative material.
      6. The device of any of claims 1 to 5, wherein an optimal area ratio of the areas A₂/A₁ is based on one or more of the distance h₁, the height of thermoelectric pillar h₂, thermal properties of the materials used in the thermoelectric generator network, thermal contact resistance between the thermoelectric material and the electrodes, or a heat transfer coefficients at the surfaces of the top and bottom electrodes.
      7. The device of claim 4, wherein an optimal area ratio of the areas A₂/A₁ is based on the distance h₁, the height of thermoelectric pillar h₂, thermal properties of the materials used in the thermoelectric generator network, thermal contact resistance between the thermoelectric material and the electrodes, and heat transfer coefficients at the surfaces of the top and bottom electrodes.
      8. The device of any of claims 1 to 7, further comprising a second thermoelectric unit, the second thermoelectric unit comprising:
a top electrode having a third spacer extending therefrom;
a bottom electrode having a fourth spacer extending therefrom towards the third spacer; and
a pillar disposed between the top and bottom electrodes,
wherein one or more of the top electrode of the second thermoelectric unit is connected to the top electrode of the first thermoelectric unit via a wire, or the bottom electrode of the second thermoelectric unit is connected to the bottom electrode of the first thermoelectric unit via a wire.
   9. The device of any of claims 1 to 8, wherein the thermoelectric generator network produces a maximal power density approximately in the range of about 5 μW/cm² to about 60 μW/cm².
   10. The device of any of claims 1 to 9, wherein the bottom electrode is configured to abut a skin surface to absorb heat therefrom and the top electrode is configured to dissipate heat therefrom into an ambient environment.
   11. The device of any of claims 1 to 10, wherein the height h₂ of the pillar is substantially equal to one or more of the first length or the second length.
   12. The device of any of claims 1 to 11, wherein the distance h₁ is substantially equal to a sum of h₂ of the pillar, the first length, and the second length.
   13. The device of any of claims 1 to 12, wherein the height h₂ of the pillar is substantially equal to each of the first length and the second length.
   14. The device of any of claims 1 to 13, wherein one or more of the first length or the second length is determined based on the distance h₁ or the height h₂.
   15. The device of any of claims 1 to 14, wherein the device is a wearable device.
   16. The device of claim 12, wherein the flexibility of the wearable device is such that the wearable device is configured to be bent upon itself at a bending radius in approximately a range of about 1 centimeter to about 10 centimeters.
   17. The device of any of claims 1 to 16, further comprising a fabric disposed between the top and bottom electrodes.
   18. The device of claim 17, wherein the fabric includes a plurality of openings or is loosely knitted through which the pillar passes.
   19. A flexible thermoelectric generator network, comprising:
a plurality of thermoelectric units, each thermoelectric unit comprising:
   a top electrode defined by an area A₃;
   a bottom electrode defined by an area A₁ disposed a distance h₁ apart from the top electrode; and
   a pillar defined by an area A₂ and a height h₂, the pillar being disposed between the first electrode and the second electrode to be engaged between a first portion of the first electrode and a second portion of the second electrode,
   wherein at least a pair of the top electrodes of the plurality of thermoelectric units are connected to one another and at least a pair of the bottom electrodes of the plurality of thermoelectric units are connected to one another,
   wherein the height h₂ of the pillar is smaller than a distance h₁ between the top and bottom electrodes, and
   wherein the area A₃ is greater than or equal to the area A₁, which is greater than the area A₂.
      20. The network of claim 13, wherein the first portion further comprises a first spacer extending from the top electrode and the second portion further comprises a second spacer extending from the bottom electrode, the first and second spacers being configured to engage the pillar therebetween.
      21. The network of claim 20 or claim 21, wherein the top and bottom electrodes and the first and second spacers are comprised of the same material.
      22. The network of any of claims 19 to 21, wherein an output power density of the thermoelectric unit having the first and second spacers is about 3 times to about 5 times greater than the output power density of a thermoelectric unit that is devoid of the first and second spacers, the output power density of the thermoelectric unit that is devoid of the first and second spacers being measured at a same cross-sectional area and thermal condition as the thermoelectric unit.
      23. The network of any of claims 19 to 22, wherein the plurality of thermoelectric units are substantially devoid of one or more of ceramics, polymers, substrates, or insulative materials between the top and bottom electrodes.
      24. The network of any of claims 19 to 23, wherein each of the top and bottom electrodes is substantially devoid of contact with a substrate.
      25. The network of any of claims 19 to 24, wherein one or more of the top electrode or the bottom electrode includes a chamfered edge configured to prevent the edges of thermoelectric units from cutting skin.
      26. The network of any of claims 19 to 25, wherein the distance h₁ is substantially equal to a sum of h₂ of the pillar, the first length, and the second length.
      27. The network of any of claims 19 to 26, wherein an output power density increases with the convective heat transfer coefficient above the pair of top electrodes and is a non-linear function of the height h₂.

One skilled in the art will appreciate further features and advantages of the disclosures based on the provided for descriptions and embodiments. Accordingly, the inventions are not to be limited by what has been particularly shown and described. All publications and references cited herein are expressly incorporated herein by reference in their entirety.

What is claimed is:

1. A flexible thermoelectric generator device, comprising:
a thermoelectric generator network that includes a first thermoelectric unit comprising:
a top electrode having a first spacer extending a first length therefrom, the top electrode being defined by an area A₃;
a bottom electrode having a second spacer extending a second length therefrom towards the first spacer, the bottom electrode being defined by an area A₁ and being a distance h₁ apart from the top electrode; and
a pillar disposed between the first spacer and the second spacer to separate the first spacer from the second spacer, the pillar being configured to transmit thermal energy between the top and bottom electrodes, the pillar being defined by an area A₂ and a height h₂ that is independent of the distance h₁;
wherein the area A₃ is larger than the area A₁, and
wherein a ratio of the areas A₂/A₁ is based on the height h₂ of the pillar or the height h₂ of the pillar is based on the ratio of the areas A₂/A₁.

2. The device of claim 1, wherein the height h₂ of the pillar is smaller than the distance h₁.

3. The device of claim 1, wherein a ratio of the area A₃ to the area A₁ is approximately in a range of about 1 to about 25.

4. The device of claim 1, wherein an optimal area ratio of the areas A₂/A₁ is based on one or more of the distance h₁, the height of thermoelectric pillar h₂, thermal properties of the materials used in the thermoelectric generator network, thermal contact resistance between the thermoelectric material and the electrodes, or a heat transfer coefficients at the surfaces of the top and bottom electrodes.

5. The device of claim 5, wherein an optimal area ratio of the areas A₂/A₁ is based on the distance h₁, the height of thermoelectric pillar h₂, thermal properties of the materials used in the thermoelectric generator network, thermal contact resistance between the thermoelectric material and the electrodes, and heat transfer coefficients at the surfaces of the top and bottom electrodes.

6. The device of claim 1, further comprising a second thermoelectric unit, the second thermoelectric unit comprising:
a top electrode having a third spacer extending therefrom;
a bottom electrode having a fourth spacer extending therefrom towards the third spacer; and
a pillar disposed between the top and bottom electrodes,
wherein one or more of the top electrode of the second thermoelectric unit is connected to the top electrode of the first thermoelectric unit via a wire, or the bottom electrode of the second thermoelectric unit is connected to the bottom electrode of the first thermoelectric unit via a wire.

7. The device of claim 1, wherein the thermoelectric generator network produces a maximal power density approximately in the range of about 5 μW/cm² to about 60 μW/cm².

8. The device of claim 1, wherein the height h₂ of the pillar is substantially equal to one or more of the first length or the second length.

9. The device of claim 1, wherein the distance h₁ is substantially equal to a sum of h₂ of the pillar, the first length, and the second length.

10. The device of claim 1, wherein one or more of the first length or the second length is determined based on the distance h₁ or the height h₂.

11. The device of claim 1, wherein a temperature difference defined across the distance h₁ is lower than a temperature difference defined across the distance h₁ in the absence of the first spacer or the second spacer.

12. The device of claim 1, wherein the device is a wearable device.

13. A flexible thermoelectric generator network, comprising:
a plurality of thermoelectric units, each thermoelectric unit comprising:
a top electrode defined by an area A₃;
a bottom electrode defined by an area A₁ disposed a distance h₁ apart from the top electrode; and
a pillar defined by an area A₂ and a height h₂, the pillar being disposed between the first electrode and the second electrode to be engaged between a first portion of the first electrode and a second portion of the second electrode,
wherein at least a pair of the top electrodes of the plurality of thermoelectric units are connected to one another and at least a pair of the bottom electrodes of the plurality of thermoelectric units are connected to one another,
wherein the height h₂ of the pillar is smaller than a distance h₁ between the top and bottom electrodes, and
wherein the area A₃ is greater than or equal to the area A₁, which is greater than the area A₂.

14. The network of claim 13, wherein the first portion further comprises a first spacer extending from the top electrode and the second portion further comprises a second spacer extending from the bottom electrode, the first and second spacers being configured to engage the pillar therebetween.

15. The network of claim 13, wherein the top and bottom electrodes and the first and second spacers are comprised of the same material.

16. The network of claim 13, wherein an output power density of the thermoelectric unit having the first and second spacers is about 3 times to about 5 times greater than the output power density of a thermoelectric unit that is devoid of the first and second spacers, the output power density of the thermoelectric unit that is devoid of the first and second spacers being measured at a same cross-sectional area and thermal condition as the thermoelectric unit.

17. The network of claim 13, wherein the plurality of thermoelectric units are substantially devoid of one or more of ceramics, polymers, substrates, or insulative materials between the top and bottom electrodes.

18. The network of claim 13, wherein each of the top and bottom electrodes is substantially devoid of contact with a substrate.

19. The network of claim 13, wherein one or more of the top electrode or the bottom electrode includes a chamfered edge configured to prevent the edges of thermoelectric units from cutting skin.

20. The network of claim 13, wherein an output power density increases with the convective heat transfer coefficient above the pair of top electrodes and is a non-linear function of the height h₂.
